(19) United States
(12) Patent Application Publication
(10) Pub. No.: US 2012/0231246 A1
(43) Pub. Date: Sep. 13, 2012

(54) PROCESS FOR REMOVAL OF BACKSIDE COATING FROM SUBSTRATE

(76) Inventors: John E. Madocks, Tucson, AZ (US); Walter Seaman, Tucson, AZ (US); Phong Ngo, Tucson, AZ (US)

(21) Appl. No.: 13/272,713

(22) Filed: Oct. 13, 2011

Related U.S. Application Data
(60) Provisional application No. 61/392,609, filed on Oct. 13, 2010.

(51) Int. Cl. B32B 17/00; B05D 1/02; B32B 7/02; B05D 3/00; C23C 14/34; C23C 16/50; B05D 3/12

(52) U.S. Cl. 428/213; 427/569; 204/192.1; 428/426

(57) ABSTRACT

A process for producing plasma coated glass substrates free of back side coating (BSC) is provided. A low-E glass coated structure is also provided that uses a BSC as a protective coating that promotes transport and handling of low-E glass that is then subsequently delaminated. A thin film is deposited on the back side of the glass substrate before the top side of the glass is coated. Then, during the sputter down process, BSC occurs as normal and deposits over this back side film (BSF). In a subsequent process, outside the vacuum chamber, the glass back side is washed or otherwise delaminated. The BSF composition is selected to make the BSC easily removed in this wash process or other delamination process.

### RELATED APPLICATIONS

This application claims priority benefit of U.S. Provisional Application Ser. No. 61/392,609 filed Oct. 13, 2010, the contents of which are hereby incorporated by reference.

### FIELD OF THE INVENTION

The present invention relates in general to thin film coating of architectural glass and in particular to a process for removal of extraneous back side coating.

### BACKGROUND OF THE INVENTION

In the sputter deposition of architectural glass, cut sheets of glass or full-size sheets are placed on conveyor rolls and transported through a vacuum chamber. In the process section of the vacuum chamber, multiple sputter cathodes deposit films on the glass to make end products such as low-E glass windows. During the sputter deposition process, while the preponderance of sputtered atoms hit the top side of the glass, some amount of coating reaches the back side of the glass. This is called back side coating (BSC). BSC is very problematic in the low-E glass coating industry. The BSC is often thick enough that it can be optically seen by the end customer (homeowner or architect) and the result is a rejected window. Because BSC is difficult to see unless the light is just right, often rejection of the window occurs during the installation of the glass, e.g. in the home thereby making replacement expensive and logistically problematic.

In order to reduce or eliminate BSC, many techniques have conventionally been tried. These attempts include positioning substrate back side condensate shields as close to the glass as possible and using an ion source to etch clean the back side after the BSC has occurred. These techniques have not been successful in part, owing to the difficulty in placing the shields close to the glass because coating on the shields builds up and scratches the back side of the glass substrate. The use of ion sources to etch the BSC is promising, but because the BSC is thick, too many ion sources are required to be an economical solution for high throughput application.

Thus, there exists a need for an improved, practical method to reduce or eliminate BSC. There further exists a need for a glass that has a desired backside film while eliminating BSC.

### SUMMARY OF THE INVENTION

A process for producing plasma coated glass substrates free of back side coating (BSC) is provided. A low-E glass coated structure is also provided that uses a BSC as a protective coating that promotes transport and handling of low-E glass that is then subsequently delaminated. A thin film is deposited on the back side of the glass substrate before the top side of the glass is coated. Then, during the sputter down process, BSC occurs as normal and deposits over this back side film (BSF). In a subsequent process, outside the vacuum chamber, the glass back side is washed or otherwise delaminated. The BSF composition is selected to make the BSC easily removed in this wash process or other delamination process.

The BSF is either a single film layer or a laminate of multiple layers. In the instance when a BSF is a laminate of multiple layers, removal of an overlying BSC occurs through removal of all of the BSF layers, some of the BSF layers, or simply delamination of the BSC without any removal of BSF layers.

The BSF in one embodiment is a water-soluble coating that dissolves during water washing thereby causing the BSC overcoating to release from the back side of the glass substrate. Alternatively, the BSF is a coating that makes it easy for the BSC to be cleaned in the wash or other delamination process.

### BRIEF DESCRIPTION OF THE DRAWINGS

FIG. 1 is a cross-sectional view of an inventive glass structure and the final product post washing based on the nature of the inventive back side film (BSF).

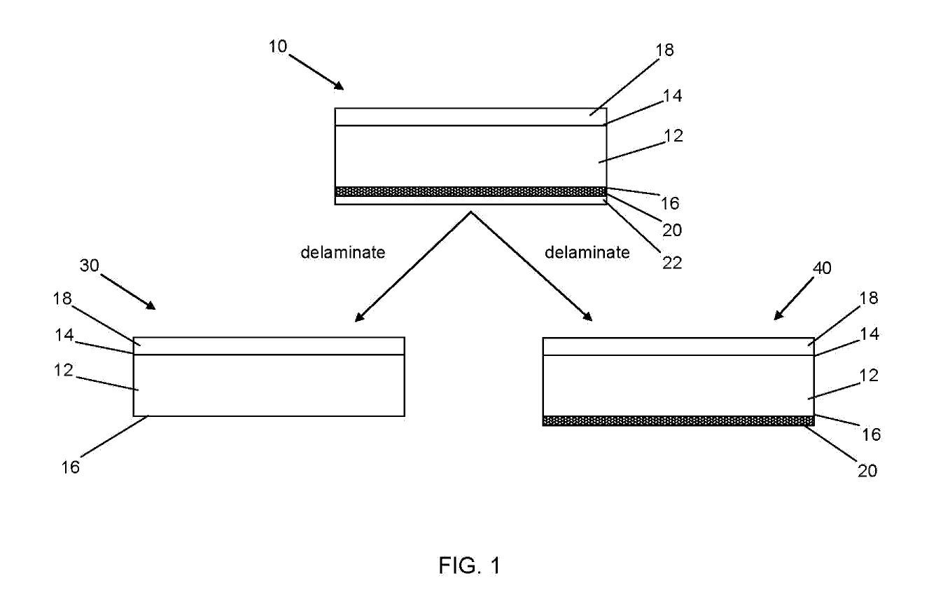

FIG. 2 is a flowchart of an exemplary method for implementing embodiments of the invention.

### DETAILED DESCRIPTION OF THE PREFERRED EMBODIMENTS

The present invention has utility as a process for producing plasma coated glass substrates free of BSC. A low-E glass coated structure is also provided that uses a BSC as a protective coating that promotes transport and handling of low-E glass that is then subsequently delaminated.

According to the present invention, a thin backside film (BSF) is deposited on the back side of the glass substrate before the top side of the glass is coated. Then, during the sputtering process, BSC occurs as normal and deposits onto the BSF. In a subsequent process, outside the vacuum deposition chamber, the glass back side is washed or otherwise treated to induce delamination of at least the BSC and optionally the BSF as well. The BSF composition is selected to make the BSC easily removed in this wash process or other delamination process. It is appreciated that a BSF is either a single film layer or a laminate of multiple layers. In the instance when a BSF is a laminate of multiple layers, removal of an overlying BSC occurs through removal of all of the BSF layers, or removal of some of the BSF layers, or simply delamination of the BSC without any removal of BSF layers.

The BSF in one embodiment is a water-soluble coating that dissolves during water or other solvents washing thereby causing the BSC overcoating to release from the back side of the glass substrate. Suitable solvents operative for BSC removal illustratively include water; alcohols such as C₁-C₁₂ alcohols of methanol, ethanol, isopropanol, and hexanol; glycols such a ethylene glycol, propylene glycol, butylene glycol, and room temperature liquid polyethylene glycols; ethers such as (C₁-C₆)—O—(C₁-C₆); acetone; alkanes such as hexanes, octanes, and petroleum distillates; aromatics such as toluene, and xylenes; and miscible combinations thereof. It is further appreciated that additives are readily added to the solvent to promote BSC delamination. Such additives illustratively include surfactants, pH modifiers, plasticizers, and emulsifiers.

Preferably, the BSF is a coating that makes it easy for the BSC to be cleaned in the wash or other delamination process. For instance, a hydrophobic coating such as a fluorinated film is used. Regardless of the nature of the BSF, it is a critical aspect of the present invention that the BSC has adhesion to the BSF that is sufficiently weak so as to be delaminated at least in part by the a process of at least one of ISO 9211-4 abrasion resistance test (5), the adhesion test (6), or the solubility test thereof(8). While abrading, adhesively removing the BSC, or solubilizing a BSF underlying the BSC are all suitable methods of BSC removal, it is appreciated that actual removal of the BSC optionally occurs by other techniques, yet regardless of the technique, the BSC removal satisfies at least one of the above delineated tests per ISO 9211-4. ISO 9211-4 are hereby incorporated by reference in its entirety. These other removal techniques illustratively include air alone, or with particulate that is non-damaging to the glass substrate impingement; vacuum draw; air knife impingement; application of a laminate film that peels off the BSC; contact with a sticky roller; incidental passive delamination; ultrasonic impingement; and mechanical abrasion with a cloth or other substance.

An inventive structure is shown generally at 10 where relative thicknesses are distorted for visual clarity. A conventional glass substrate 12 has a top side surface 14 and a back side surface 16. An inventive BSF 20 is applied to a back side surface 16 prior to plasma deposition. A low-E glass coating 18 is plasma deposited to top side surface 14 and simultaneously extraneous BSC 22 is deposited. Upon washing, as denoted by the arrows, a final product 30 or 40 is obtained with the difference therebetween being whether the BSF 20 is retained on back side surface 16. BSF 20 is removed in product 30 when BSF is water soluble or retained in product 40 when BSF 20 is a hydrophobic glass coating film.

Compositions that form water-soluble BSFs illustratively include salts dried from water-soluble organic and inorganic salt solutions, polyacrylic acids, polyvinyl pyrrolidones, poly(diallyl dialkyl ammonium chlorides), cellulose carboxyalkyl ethers, cellulose hydroalkyl ethers, dextran, chitosan, cellulose alkyl ethers, polyethylene glycols, polylactic acids, or copolymers thereof.

The BSF 20 is illustratively deposited by plasma enhanced chemical vapor deposition (PECVD), evaporation, spray coating, doctor blade, and sputtering. Optionally, a liquid film is applied that is subsequently cross-linked or a monomer that adheres directly to the backside to form the BSF 20. A basis of the present invention is to deposit the BSF 20 first, before BSC 22 has occurred. It is appreciated that forming of the BSF 20 on the topside 14 will preclude adhesion of the subsequently applied low E coating and care should be taken to avoid application of BSF material to the topside 14.

It is appreciated that the BSC 22 is removed immediately after plasma deposition of the top side coating or retained in place through manufacture and even after installation. The BSF operates as back side protective coating against incidental damage associated with handling or transport.

While acting to make BSC 22 easy to remove, it is appreciated that the BSF 20 optionally has functionality to improve glass cleaning in later manufacturing steps or even in the final application—the home or office. A hydrophobic BSF 20 is also known as an “anti-smudge” or “anti-stain” film. These films 20 are used in cell phones and tablet PCs to reduce fingerprinting and to make the display easier to clean. These same properties can benefit the large area glass industry. Suitable agents to coat that backside to form a hydrophobic coating 20 by simply contact application illustratively include 3-aminopropyltrimethoxysilane, 3-aminopropyltriethoxysilane, 3-glycidoxypropyltrimethoxysilane, 3-glycidoxypropyltriethoxysilane, (3-glycidoxypropyl)bis(trimethylsiloxy)methylsilane, (3-glycidoxypropyl)methyldiethoxysilane, (3-glycidoxypropyl)dimethylethoxysilane, (3-glycidoxypropyl)methyldimethoxysilane, methacryloxymethyltriethoxysilane, methacryloxymethyltrimethoxysilane, methacryloxypropyldimethylethoxysilane, methacryloxypropyldimethylmethoxysilane, methacryloxypropylmethyldimethoxysilane, methacryloxypropyltriethoxysilane, methoxymethyltrimethylsilane, 3-methoxypropyltrimethoxysilane, 3-methacryloxypropyldimethylchlorosilane, methacryloxypropylmethyldichlorosilane, methacryloxypropyltrichlorosilane, 3-isocyanatopropyldimethylchlorosilane, 3-isocyanatopropyltriethoxysilane, and bis(3-triethoxysilylpropyl)tetrasulfide. Owing to the high throughput of a typical low E glass manufacture facility and the prohibition that the BSF 20 be applied to the topside, a plasma deposition of a BSF 20 is preferred. Such a BSF 20 is readily applied by introducing a gaseous fluorinated precursors into a plasma CVD reaction occurring adjacent to the backside to deposit fluorinated hydrophobic BSFs. Representative precursors include C₁-C₆ fluoroalkyls and perfluoralykls such as fluoroethene, fluoroethane, fluorobutane, perfluoroethene, perfluoroethane perfluorobutane; C₁-C₆ fluorocarboxylates and perfluorocarboxylates; fluorosilanes, perfluorosilanes, fluorosiloxanes, perfluorosiloxanes, chlorofluorocarbons, fluorochlorosilanes, fluoroaminosilanes, fluoromethoxysilanes, fluoroethoxisilanes, fluorocyclobutane, fluoropropane, perfluoropropane, various fluorinated alkyl silanes, various fluorinated cycloalkanes, and combinations thereof. It is appreciated that plasma, deposition of salts is also well known to the art.

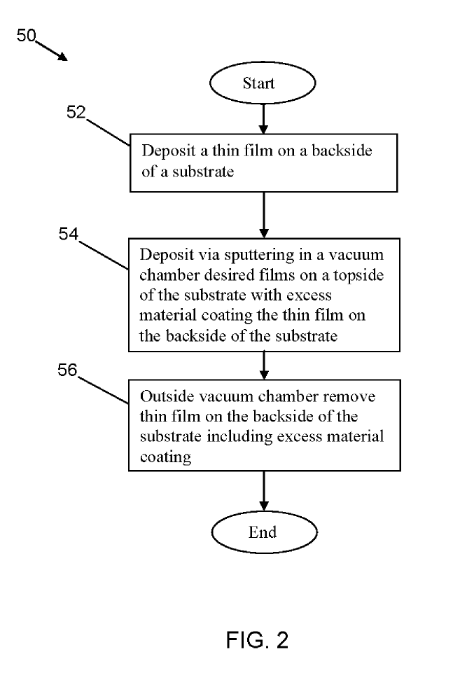

FIG. 2 is a flowchart of an exemplary method 50 for implementing embodiments of the invention. At step 52, a thin film is deposited on a backside of a substrate that will be subjected to a sputtering process for a top side treatment. At step 54, desired films are deposited via sputtering in a vacuum chamber on a topside of the substrate with excess material coating the thin film on the backside of the substrate. At step 56, the substrate is removed from the vacuum chamber, and the thin film on the backside of the substrate including excess material coating is removed.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A process for removal of back side coating from a coated structure comprising:
applying a back side film to a back side surface of a glass substrate;
then plasma depositing a coating onto a top side surface and to a lesser extent to the back side film to form a back side coating, said back side coating has an adhesion to the back side film that is insufficient to pass at least one of ISO 9211-4; and
removing said back side coating, after the plasma depositing.

2. The process of claim 1 wherein said back side film is water soluble and removed by wash removing.

3. The process of claim 2 wherein said back side film is one of: water-soluble organic and inorganic salt solutions, polyacrylic acids, polyvinyl pyrrolidones, poly(diallyl dialkyl ammonium chlorides), cellulose carboxyalkyl ethers, cellulose hydroalkyl ethers, dextran, chitosan, cellulose alkyl ethers, polyethylene glycols, polylactic acids, copolymers thereof or combinations thereof.

4. The process of claim 1 wherein said removing occurs during manufacture of the structure.

5. The process of claim 1 wherein said substrate is planar.

6. The process of claim 1 wherein said back side film is hydrophobic and retained on the back side surface after said removing.

7. The process of claim 6 wherein said back side film is one of: a monomeric silane, a fluoropolymer or a perfluoropolymer.

8. The process of claim 1 wherein said applying of said back side film is by plasma enhanced chemical vapor deposition (PECVD), evaporation, spray coating, doctor blade, or sputtering.

9. The process of claim 1 wherein said coating is a low-E coating.

10. The process of claim 1 wherein said back side coating is removed by air impingement, or air impingement with particulate that is non-damaging to said substrate; vacuum draw; air knife impingement; application of a laminate film; contact with a sticky roller; incidental passive delamination; ultrasonic impingement; and mechanical abrasion with a cloth or other substance.

11. A structure comprising:
a planar glass substrate having a top side surface and a back side surface;
a low-E coating on the top side surface;
a back side film on the back side surface; and
a back side coating formed from an excess of said low-E coating migrating from said top side surface to the back side film said back side coating has an adhesion to the back side film that is insufficient to pass at least one of ISO 9211-4.

12. The structure of claim 11 wherein a thickness ratio between the low-E coating on the top side surface and the excess low-E coating on the back side surface is greater than 20.

13. The structure of claim 11 wherein the back side film is hydrophobic.

14. The structure of claim 11 wherein the back side film is water soluble.

15. The structure of claim 11 wherein the back side film is a multiple layer laminate.

16. The structure of claim 11 wherein the back side film is a single layer.
